(19) United States
(12) Patent Application Publication
(10) Pub. No.: US 2005/0046309 A1
(43) Pub. Date: Mar. 3, 2005

(54) Micro-compressor actuated by piezoelectric actuator

(75) Inventors: Jong-won Kim, Seoul (KR); Hyun-se Kim, Seoul (KR); Ki-baik Kwon, Donghae-si (KR)

Correspondence Address: MERCHANT & GOULD PC, P.O. BOX 2903, MINNEAPOLIS, MN, 55402-0903, US

(73) Assignee: Seoul National University Industry Foundation, Kwanak-gu (KR)

(21) Appl. No.: 10/691,867

(22) Filed: Oct. 23, 2003

(30) Foreign Application Priority Data
Oct. 23, 2002 (KR) 10-2002-64994

(51) Int. Cl. H01L 41/09

(52) U.S. Cl. 310/328

(57) ABSTRACT

The present invention relates to a micro-compressor equipped with plurality of compression means comprising a vibrating plate forming the outer wall of the pressure chamber, inlet valve and outlet valve attached to the vibrating plate. The compression means are operated by a certain number of piezo-actuators that are attached to the vibrating plate, inlet valve and outlet valve and perform the function of indraft, compression and exhaustion of working fluid. The piezo-actuators enable the swift operation and precise control in the micro-refrigerator with the size of semiconductor chip. The compression means do not alter the flowing direction of working fluid and the openings for the indraft and exhaustion of working fluid can be aligned in a straight line. As a result, plurality of compression means can be arranged in parallel to maximize the compression capacity.

### BACKGROUND OF THE INVENTION

1. Field of the Invention

The present invention relates to the micro-compressor, and more specifically to the micro-compressor for the micro-refrigerator which is used in CPU or the integrated circuit of movable device, where a lot of heat is generated in a small area and it is needed to keep the temperature constant so as not to harm the efficiency of the chip.

2. Background of the Related Art

A large number of transistors are integrated in the main chip comprising the CPU of computer. According to “Moor's Law”, that is, the price of the chip goes down by a half while the performance of the chip increases by twofold, the degree of integration is expected to increase further. For example, there are 42,000,000 transistors in the Intel pentium4 chip, which is prevailing nowadays. According to “Moor's Law”, it is prospected that 250,000,000 transistors can be integrated into CPU until the year of 2010. As the degree of integration increases, as predicted by “Moor's Law”, more energy is used in the calculation process of chips and more heat is generated on the surface of the chips. The performance of the semiconductor is sensitive to the temperature. As a result, the research for the treatment of the large amount of heat generating on the surface of the chip, is executed actively.

In prior art, a cooling fan was attached to the surface of CPU, and additional fin was added to enhance the cooling effect. But, the cooling fan makes much noise and does not adequate for the notebook computer or mobile communication device, which are in the trend of miniaturization.

To solve above-mentioned problems, the micro refrigerator, which is the size of semiconductor chip and can be attached to the chip directly, for the maintenance of constant temperature of chip is under vigorous research. The mainstream of this research is the passive type micro-refrigerator, which does not require additional power source. There are many passive type micro-refrigerator: the micro-refrigerator, where the material with high conductivity is place between the heat producing chip (high temperature part) and the low temperature part so that the heat is transferred from the high temperature part to the low temperature part; the micro-refrigerator, where the heat generated at the high temperature part evaporates the refrigerant and the evaporated refrigerant give off the heat to the low temperature part by convection. The latter kind of micro-refrigerators are CPL (Micro Capillary Pumped Loop), Micro Heat Pipe or the combination of Micro Heat Pipe with heat spreader. But, above-mentioned passive type micro-refrigerator has too small capacity to meet the great amount of heat produced at the currently used semiconductor chip.

To meet the above-mentioned shortages, active type micro-refrigerator with the structure of ordinary refrigerator was developed, which is composed of compressor, evaporator, expander and condenser and operated by an additional external power source to maximize the cooling capacity. In the development of above-mentioned active type micro-refrigerator, the need for the development of micro-compressor is emphasized. But, the micro-compressor is hard to be manufactured at the size of semiconductor chip, and the capacity is relatively small.

### SUMMARY OF THE INVENTION

The present invention was devised to solve above said problems of the prior art, and the purpose of present invention is to provide a micro-compressor which is small but has enough compression capacity to be applied to the semiconductor chip, and easy for control.

The present invention is about the micro-compressor equipped with plurality of compression means comprising a vibrating plate forming the outer wall of the pressure chamber, inlet valve and outlet valve attached to the vibrating plate.

The compression means are operated by a certain number of piezo-actuators which are attached to the vibrating plate, inlet valve and outlet valve and perform the function of indraft, compression and exhaustion of working fluid.

The piezo-actuators enable the swift operation and precise control in the micro-refrigerator with the size of semiconductor chip. The compression means do not alter the flowing direction of working fluid and the openings for the indraft (inlet hole) and exhaustion (outlet hole) of working fluid can be aligned in a straight line. As a result, plurality of compression means can be arranged in parallel to maximize the compression capacity.

### BRIEF DESCRIPTION OF THE DRAWINGS

These and other objects of the present invention will become more readily appreciated and understood from a consideration of the following detailed description of the preferred embodiment when taken together with the accompanying drawings, where:

FIG. 1 is a plane perspective view of the micro-compressor according to the present invention;

FIG. 2a is a rear perspective view of the first embodiment of the micro-compressor according to the present invention;

FIG. 2b is a rear perspective view of the first embodiment of the micro-compressor according to the present invention;

FIG. 2c is a cross-sectional perspective view of the first embodiment of the micro-compressor according to the present invention;

FIG. 3a is a side view of the piezo-actuator used as a driving means for the micro-compressor according to the present invention;

FIG. 3b is a side view of the piezo-actuator used as a driving means for the micro-compressor according to the present invention, operating upward;

FIG. 3c is a side view of the piezo-actuator used as a driving means for the micro-compressor according to the present invention operating downward;

FIG. 4a, 4b and 4c are the perspective view of the compression means of the micro-compressor according to the present invention, illustrating the operating procedures of the compression means;

FIG. 5a is a rear perspective view of the second embodiment of the micro-compressor according to the present invention;

FIG. 5b is a rear perspective view of the second embodiment of the micro-compressor according to the present invention;

FIG. 5c is a cross-sectional perspective view of the second embodiment of the micro-compressor according to the present invention;

REFERENCE NUMERALS IN DRAWINGS

| | |
|---|---|
| 1 | micro-compressor |
| 2 | center hole |
| 3 | channel |
| 4 | penetrating hole |
| 10 | compression means |
| 11 | outlet valve |
| 12 | inlet valve |
| 13 | upper vibrating plate |
| 14 | lower vibrating plate |
| 15 | round plate |
| 16 | outlet hole |
| 17-26 | piezo-actuator |
| 27 | pressure chamber |
| 28 | inlet hole |
| 31, 32 | piezoelectric element |
| 41-44 | flip valve |
| 45 | inlethole |
| 46 | outlet hole |

### DETAILED DESCRIPTION OF PREFERRED EMBODIMENTS

The purposes of present invention is achieved by providing micro-compressor wherein, a certain number of compression means are disposed on the sheet member and the working fluid beneath said sheet member is compressed and then sent to the upper side of the sheet member.

It is preferred that the compression means comprises: a pressure chamber, which is located at the inner part of said second compression means; vibrating plate, which comprises the outer wall of the pressure chamber and can be deformed to transform the volume of the pressure chamber; inlet valve, which can be opened and closed for the indraft of working fluid into the pressure chamber; and outlet valve, which can be opened and closed for the exhaustion of working fluid out of the pressure chamber.

It is preferred that the piezo-actuators are formed through inserting insulator between a pair of piezo-electric element and then joing the piezo-electric element and insulator together.

The preferred embodiment is illustrated in the following detailed description referring to the accompanying drawings.

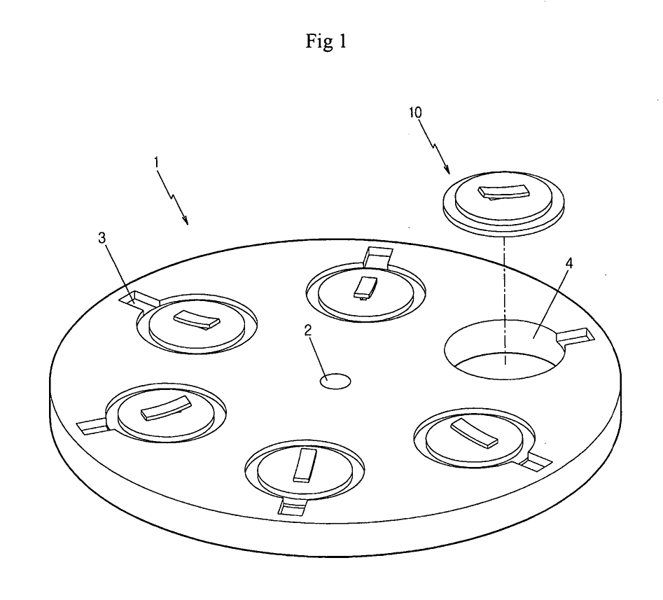

FIG. 1 is a plane perspective view of the micro-compressor according to the present invention. As illustrated in FIG. 1, the micro-compressor 1 according to the present invention is equipped with compression means 10, which are disposed on the round sheet symmetrically. In the first embodiment of present invention, six compression means 10 are symmetrically arranged in the penetrating hole 4 along the circumference of the round sheet at the angle of 60°. The diameter of the round sheet can be made around 10 mm.

At the center of the round sheet is provided a center hole 2 whose diameter is about several tens of μ m, and at the periphery of the penetrating hole 4, where compression means 10 are accommodated, is provided a channel 3. The center hole 2 and the channel 3 are used as conduit when the micro-compressor 1 is operating as a component of refrigerator.

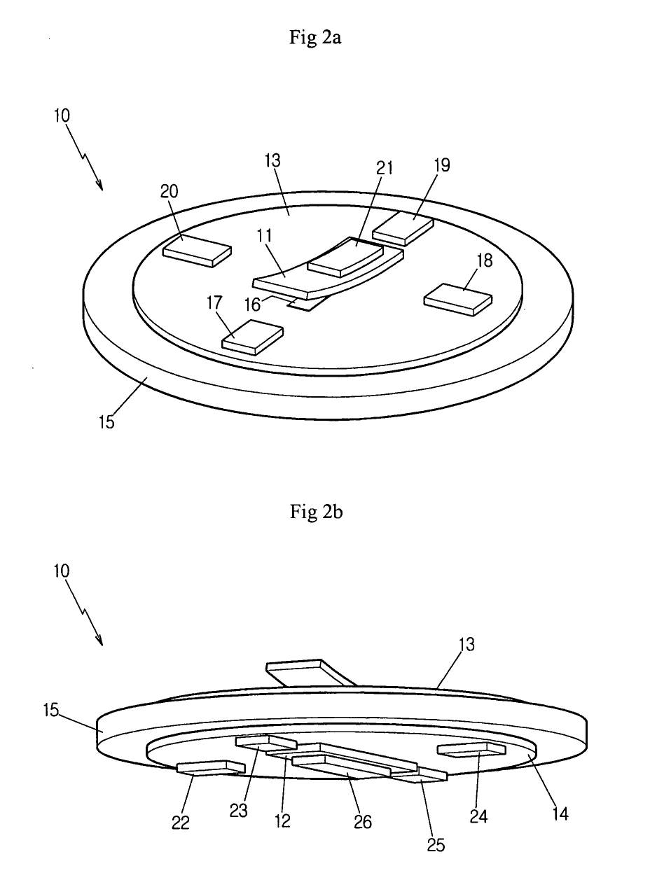

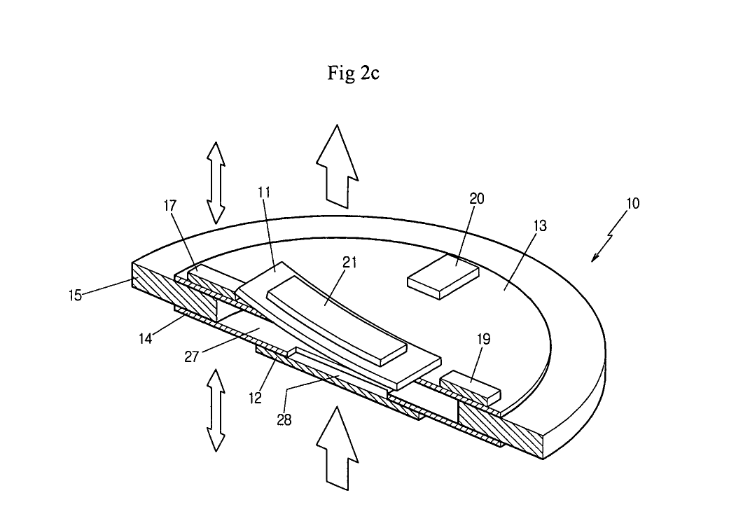

FIG. 2a, 2b and 2c are the perspective view of compression means 10 of the first embodiment according to the present invention.

As illustrated in FIG. 2a, 2b and 2c, the compression means 10 of the first embodiment according to the present invention comprises: the lower vibrating plate 14 and the upper vibrating plate 13, which are attached to the upper and lower side of the round plate 15 respectively; outlet hole 16, which is formed on upper vibrating plate 13; and inlet hole 28, which is formed on lower vibrating plate 14. The lower vibrating plate 14 and the upper vibrating plate 13 are operated by the piezo-actuators 17, 18, 19, 20, 22, 23, 24, 25 which are symmetrically arranged on the vibrating plate 13, 14, and the outlet hole 16 and the inlet hole 28 are opened or closed by the outlet valve 11 and the inlet valve 12, which are comprised of flip and the piezo-actuators 21, 26 attached on the flip. In FIG. 2c, the large arrow denotes the flowing direction of the working fluid and the small arrow denotes the opening of closing direction of the outlet valve 11 and the inlet valve 12.

The compression means 10 are produced through semiconductor procedures. That is, the compression means 10 are divided into several adequate number of layers, and every layer is processed by wet etching, DRIE (Deep Reactive Ion Etching) or CVD (Chemical Vapor Deposition) in combination with the Photolithography, and the processed layers are joined by wafer bonding process to form a symmetrical structure. And, also, the outlet valve 11 and the inlet valve 12 can be produced through using sacrificial layer. The compression means 10 can be produced through LIGA (LIthographie, Gavanoformung, Abformung) as well as semiconductor procedures.

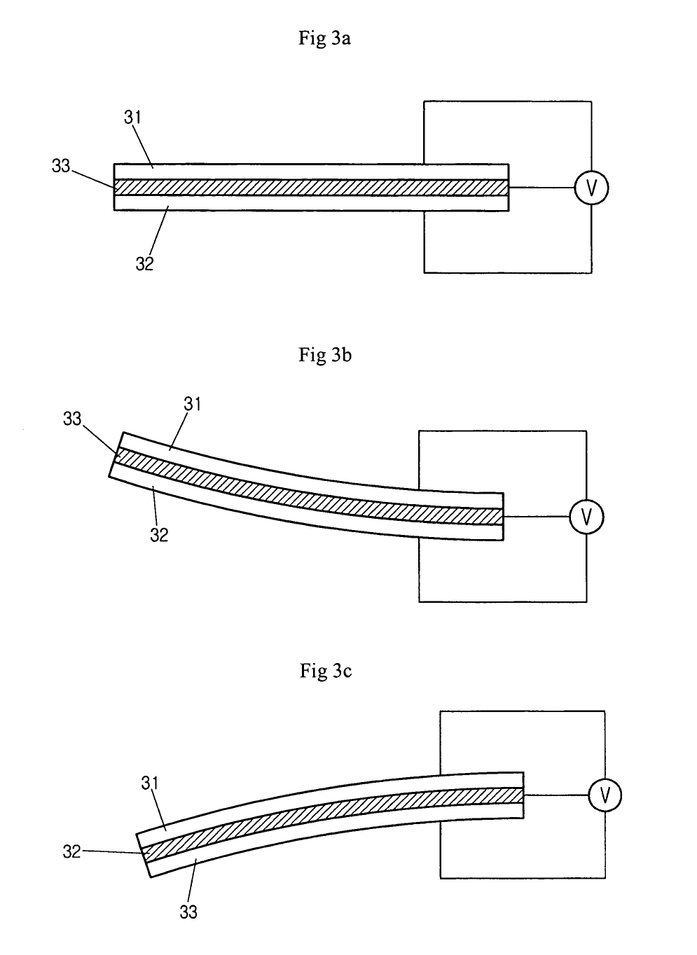

FIG. 3a and 3b are the side view of the piezo-actuator used as a driving means for the micro-compressor according to the present invention.

As illustrated in FIG. 3a, the piezo-actuators, which are operating the compression means 10, are formed through inserting elastic body 33 between a pair of sheet-shaped thin piezo-electric element 31, 32 and then joing said piezo-electric element 31, 32 and elastic body 33 together. The piezo-electric element 31, 32 have the characteristics of being extended of contracted according to the direction of the electric currents. In the piezo-actuators illustrated in FIG. 3a, the piezo-electric element 31 is contracted when applied with forward voltage, and the piezo-electric element 32 is extended when applied with reverse voltage. As the piezo-electric element 31, 32 are firmly joined together, the piezo-actuator bends to the direction of contracting piezo-electric element 31.

To the contrary, in the piezo-actuators illustrated in FIG. 3a, the piezo-electric element 31 is extended when applied with reverse voltage, and the piezo-electric element 32 is contracted when applied with forward voltage. As the piezo-electric element 31, 32 are firmly joined together, the piezo-actuator bends to the direction of contracting piezo-electric element 32.

Like the method illustrated above, when the piezo-electric element 31, 32 of the piezo-actuators 17, 18, 19, 20, 21, 22, 23, 24, 25, 26 are applied with different direction of voltage, the piezo-actuators 17, 18, 19, 20, 21, 22, 23, 24, 25, 26 deform as illustrated in FIG. 3a, 3b and 3c. The elastic body 33 is made of elastic material to move elastically with the bending motion of the piezo-electric element 31, 32, and also, the elastic body 33 is made of insulating material to cut off the current flow between the two piezo-electric element 31, 32.

Generally, the piezo-actuator has the characteristics of small time constant(i.e. quick reaction rate) and precise control, and it can generate large force in spite of the small size. A certain number of piezo-actuators operate the compression means 10 by being attached to the upper flip 11, lower flip 12, the upper vibrating plate 13, and the lower vibrating plate 14.

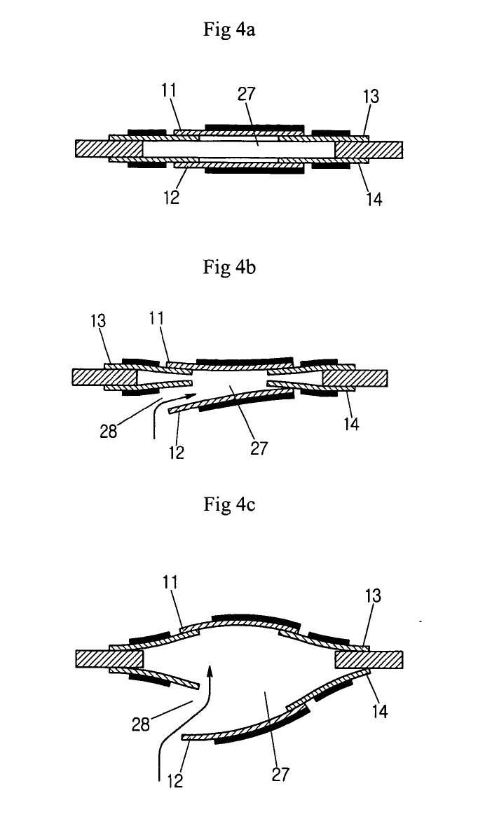

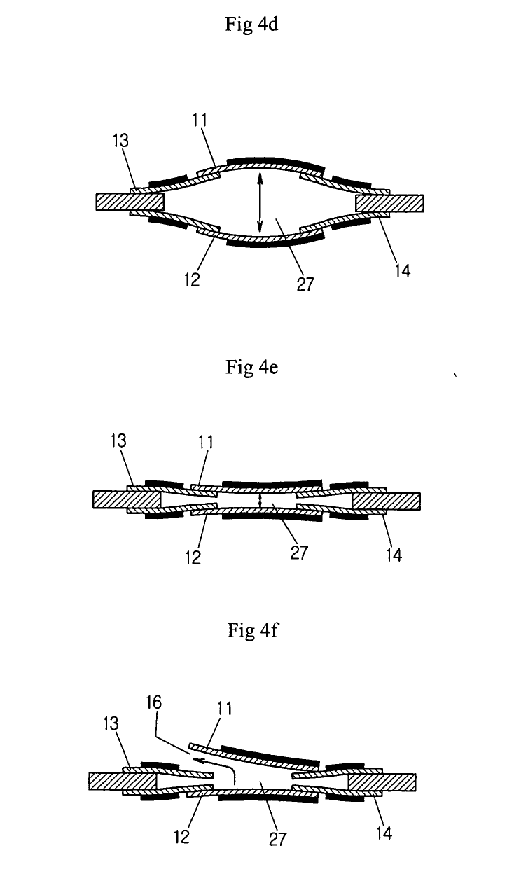

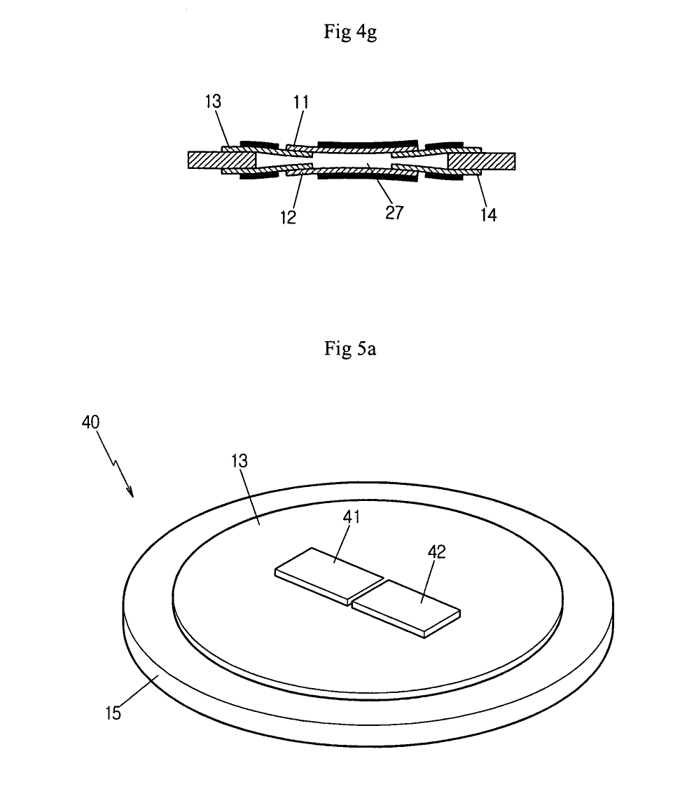

FIG. 4a, 4b, 4c, 4d, 4e, 4f and 4g are the perspective view of the compression means of the micro-compressor according to the present invention, illustrating the operating procedures of the compression means.

In FIG. 4a of the closed state, the outlet valve 11 and the inlet valve 12 of the compression means 10 are closed. In FIG. 4b of the opened inlet valve 12 state, the center area of the upper and lower vibrating plate 13, 14 subside inwardly and at the same time the inlet valve 12 is opened slightly, reducing the volume of the pressure chamber 27 and letting small amount of working fluid to go out through the inlet hole 28. In FIG. 4c of the working fluid indraft state, the outlet valve 11 is closed and the center area of the upper 13 swells outwardly and at the same time the inlet valve 12 is opened widely and the and lower vibrating plate 14 swells outwardly. At this state, the pressure of the pressure chamber 27 is lowered causing the working fluid to flow in. In FIG. 4d of the closed inlet valve 12 state, the inlet valve 12 is closed with the sucked-in working fluid. In FIG. 4e of working fluid compressing state, the center area of the upper and lower vibrating plate 13, 14 subside inwardly and with the outlet valve 11 and the inlet valve 12 closed, thus compressing the working fluid inside the pressure chamber 27. In FIG. 4f of outlet valve 11 opened state, the outlet valve 11 is opened to discharge the compressed working fluid, which was compressed while the center area of the upper and lower vibrating plate 13, 14 subside inwardly. In FIG. 4g of the outlet valve 11 and the inlet valve 12 closed state, the outlet valve 11 and the inlet valve 12 of the compression means 10 are closed and return to FIG. 4a state, finishing one cycle of the operation of compression means 10.

The first embodiment of the micro-compressor according to the present invention has the strong points of relatively simple structure and easy control as a driving means, and the present invention can be easily made into a small size of 10 mm diameter by employing piezo-actuators 17, 18, 19, 20, 21, 22, 23, 24, 25, 26. Accordingly, the present invention can be used as a active type micro-refrigerator.

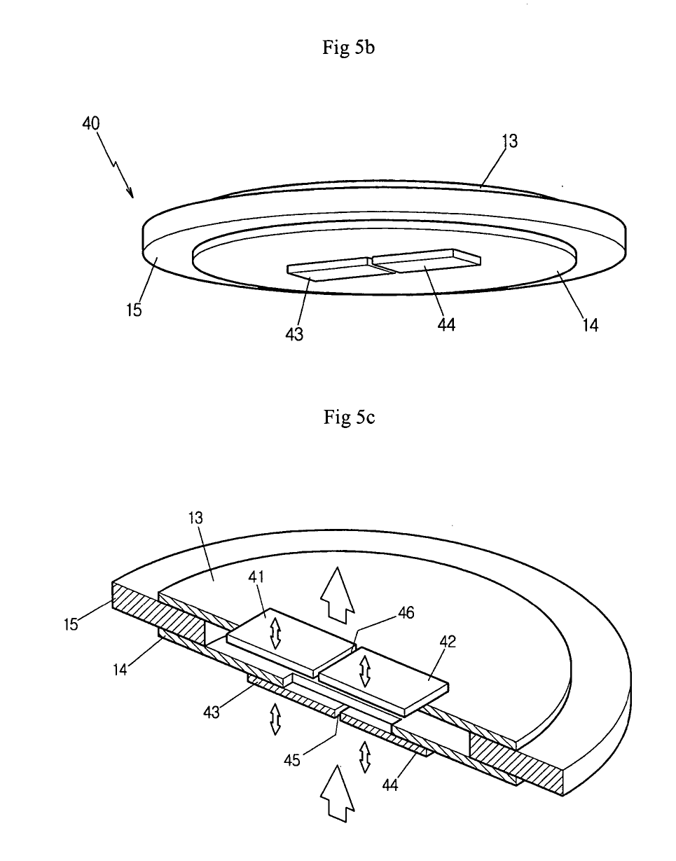

FIG. 5a, 5b and 5c are illustrated the second embodiment of the micro-compressor according to the present invention.

As illustrated in FIG. 5Sa, 5b and 5c, the compression means 40 according to the present invention is equipped with upper and lower vibrating plate 13, 14 which are disposed on the round plate 15, and a pair of flip disposed on the vibrating plate 13, 14. A pair of flips 41, 42 disposed on the upper vibrating plate 13 operate as the outlet valve, and a pair of flips 43, 44 disposed on the lower vibrating plate 14 operate as the inlet valve. The portion where a pair of flips 41, 42 meets each other becomes the outlet hole, and the portion where a pair of flips 43, 44 meet each other becomes the inlet hole.

The outlet valve and the inlet valve, which are comprised of upper and lower vibrating plate 13, 14 and flips, are operated by piezo-actuators as in the first embodiment of present invention.

In FIG. 5c, the large arrow denotes the flowing direction of the working fluid and the small arrow denotes the opening of closing direction of the flips 41, 42, 43, 44 of the outlet valve and the inlet valve.

The compression means 40 according to the second embodiment of the present invention has the same operation procedures with the first embodiment: all flips closed; inlet valve opened;

working fluid sucked-in; inlet valve closed; sucked-in working fluid compressed; and outlet valve opened.

In the second embodiment of the present invention, where the compression means 40 employs a pair of flip valves, the compression ratio, which is determined by the change rate of the volume of the pressure chamber, can be increased without enlarging the entire size of the device. That is, by employing a pair of flip valves rather than employing just one flip valve, the volume of the pressure chamber can be further increased.

### EFFECT OF THE INVENTION

As illustrated above, the present invention provides a micro-compressor with a relatively simple structure, large compression capacity and easy operation.

The micro-compressor according to the present invention has the structure suitable for the parallel arrangement of plurality of compression means 10, 40. The micro-compressor according to the present invention increases the compression capacity by employing the compression means 10 of the first embodiment and the compression means 40 of the second embodiment, which are capable of compressing the working fluid without altering it's flowing direction.

By employing piezo-actuator as a driving means, which is easy for control, capable of precise control and has small time constant with a quick reaction-rate, the micro-compressor can be easily made into a small size of around 10 mm of compressor diameter and around 2 mm of compression means diameter. And in spite of the small size, micro-compressor according to the present invention can perform a precise and swift operation.

The forgoing embodiment is merely exemplary and is not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

1. A micro-compressor, comprising:
a sheet member; and
a compression means, which is disposed on said sheet member; and,
said micro-compressor characterized in that the working fluid beneath said sheet member is compressed and then sent to the upper side of said sheet member.

2. The micro-compressor according to claim 1, wherein plurality of said compression means are disposed on said sheet member.

3. The micro-compressor according to claim 2, wherein, said compression means are arranged symmetrically.

4. The micro-compressor according to claim 1, wherein, said compression means comprising:
a pressure chamber, which is located at the inner part of said second compression means;
a vibrating plate, which comprises the outer wall of said pressure chamber and can be deformed to change the volume of said pressure chamber;
an inlet valve, which can be opened and closed for the indraft of working fluid into the pressure chamber; and
a outlet valve, which can be opened and closed for the exhaustion of working fluid out of the pressure chamber.

5. The micro-compressor according to claim 4, wherein, said vibrating plate operated by symmetrically arranged a certain number of piezo-actuators; and said inlet valve and said outlet valve operated by piezo-actuators which are disposed on said inlet valve and said outlet valve respectively.

6. The micro-compressor according to claim 5, wherein, said piezo-actuators are formed through inserting insulator between a pair of piezo-electric element and then joining said piezo-electric element and insulator together.
